(19) United States
(12) Patent Application Publication
(10) Pub. No.: US 2015/0366099 A1
(43) Pub. Date: Dec. 17, 2015

(54) WIRELESS COMMUNICATION MODULE

(71) Applicant: Samsung Electro-Mechanics Co., Ltd., Suwon-Si (KR)

(72) Inventor: Hyun Jun LEE, Pyeongtack-Si (KR)

(73) Assignee: SAMSUNG ELECTRO-MECHANICS CO., LTD., Suwon-Si (KR)

(21) Appl. No.: 14/736,530

(22) Filed: Jun. 11, 2015

(30) Foreign Application Priority Data
Jun. 11, 2014 (KR) 10-2014-0070784

(51) Int. Cl. H05K 7/02; H05K 7/06

(52) U.S. Cl. CPC H05K 7/026; H05K 7/06

(57) ABSTRACT

A wireless communication module can reduce the number of components through optimum design and improve transmission efficiency by implementing a short wiring. The wireless communication module may include a first front-end module, a second front-end module, and a wiring unit arranged between the first front-end module and the second front-end module to supply power to the first front-end module and the second front-end module. At least one capacitor may be connected to the wiring unit.

### CROSS-REFERENCE TO RELATED APPLICATION

This application claims the benefit under 35 U.S.C. Section 119 of Korean Patent Application Serial No. 10-2014-0070784, filed Jun. 11, 2014, which is hereby incorporated by reference in its entirety into this application.

### BACKGROUND

1. Technical Field

Some embodiments of the present disclosure relate to a wireless communication module.

2. Description of the Related Art

In recent times, various communication standards of wireless communication modules have been released. In particular, it is common that a front-end module including a power amplifier (PA), a low noise amplifier (LNA), etc. is connected to the outside of a WiFi IC in addition to the PA and the LNA embedded in the WiFi IC to improve the performance of a WiFi module. Further, products that have dual band support and support 5 GHz frequency band are commercialized due to the saturation of 2 GHz frequency band, interference of long term evolution (LTE) band, etc. In particular, an external front-end module may be needed to be applied to products that support high-speed throughputs from 11a to 11ac, and high-performance products are further needed according to the high speed trend and the use of high frequencies. Therefore, there is a need for the optimum design of the wireless communication module.

### SUMMARY

Some embodiments of the present disclosure may provide a wireless communication module which can reduce the number of components through optimum design and improve transmission efficiency by implementing a short wiring.

In accordance with one embodiment of the present disclosure, a wireless communication module may include a wiring unit arranged between a first front-end module and a second front-end module to supply power to the first front-end module and the second front-end module. At least one capacitor may be connected to the wiring unit.

In accordance with another embodiment of the present disclosure, a wireless communication module may include: a first front-end module; a second front-end module; a first capacitor arranged between the first front-end module and the second front-end module to be connected to a power terminal of the first front-end module and a power terminal of the second front-end module; and a second capacitor arranged between the first front-end module and the second front-end module and connected to the power terminal of the first front-end module and the power terminal of the second front-end module.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a structural diagram showing a structure of a wireless communication module in accordance with an exemplary embodiment of the present disclosure;

FIG. 2A is a partial circuit diagram showing a portion of a first front-end module shown in FIG. 1;

FIG. 2B is a partial circuit diagram showing another portion of the first front-end module shown in FIG. 1;

FIG. 3A is a partial circuit diagram showing a portion of a second front-end module shown in FIG. 1;

FIG. 3B is a partial circuit diagram showing another portion of the second front-end module shown in FIG. 1;

FIG. 4A is a layout diagram showing an embodiment in which the wireless communication module shown in FIG. 1 is arranged on a substrate;

FIG. 4B is a layout diagram enlarging a portion in which a first capacitor, a second capacitor, and a third capacitor shown in FIG. 4A are connected; and

FIG. 5 is a structural diagram showing the wireless communication module, shown in FIG. 1, formed in a multilayer structure.

### DETAILED DESCRIPTION OF THE PREFERABLE EMBODIMENTS

A matter regarding to an operational effect including a technical configuration for an object of a wireless communication module in accordance with embodiments of the present disclosure will be clearly appreciated through the following detailed description with reference to the accompanying drawings showing preferable embodiments of the present disclosure.

Further, in describing the present disclosure, descriptions of well-known techniques are omitted so as not to unnecessarily obscure the embodiments of the present disclosure. In the present specification, the terms “first,” “second,” and the like are used for distinguishing one element from another, and the elements are not limited by the above terms.

In the following detailed description of the present disclosure, reference is made to the accompanying drawings that show, by way of illustration, specific embodiments in which the present disclosure may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments. The following detailed description is, therefore, not to be taken in a limiting sense, and the scope of the embodiments is defined only by the appended claims, appropriately interpreted, along with the full range of equivalents to which the claims are entitled. In the drawings, like numerals refer to the same or similar functionality throughout the several views.

Hereinafter, preferable embodiments of the present disclosure will be described in detail with reference to the accompanying drawings so that those skilled in the art can easily practice the present disclosure.

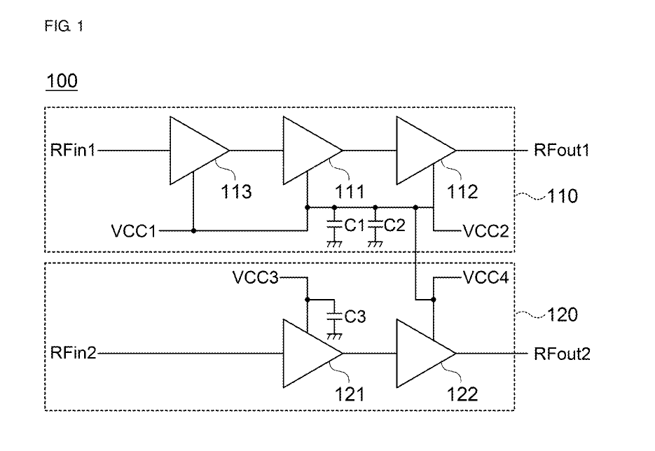

FIG. 1 is a structural diagram showing a structure of a wireless communication module in accordance with an embodiment of the present disclosure.

Referring to FIG. 1, a wireless communication module 100 may include a first front-end module 110 arranged between a first input terminal RFin1 and a first output terminal RFout1 to receive and process a first signal from the first input terminal RFin1 and a second front-end module 120 arranged between a second input terminal RFin2 and a second output terminal RFout2 to receive and process a second signal from the second input terminal RFin2. Here, the wireless communication module 100 may include various wireless communication devices such as Wi-Fi, Bluetooth, and zig-bee modules.

The first front-end module 110 may amplify the first signal having a predetermined frequency to output the amplified first signal. The first front-end module 110 may include a first amplifier 111 and a second amplifier 112 which are arranged in the form of a cascade. After the first amplifier 111 amplifies the first signal received through the first input terminal RFin1 and outputs the amplified first signal, the second amplifier 112 may amplify the first signal received from the first amplifier 111 again to output the further amplified first signal through the first output terminal RFout1. In an example of the present embodiment, the first amplifier 111 may be a drive amplifier, and the second amplifier 112 may be a power amplifier. The first signal, which is amplified and output from the first front-end module 110, may be, for example, but not limited to, a signal having a frequency band of 5 GHz.

Further, the second front-end module 120 may amplify the second signal having a predetermined frequency to output the amplified second signal. The second front-end module 120 may include a third amplifier 121 and a fourth amplifier 122 which are arranged in the form of a cascade. After the third amplifier 121 amplifies the second signal received through the second input terminal RFin2 and outputs the amplified second signal, the fourth amplifier 122 may amplify the second signal received from the third amplifier 121 again to output the further amplified second signal through the second output terminal RFout2. In an example of the present embodiment, the third amplifier 121 may be a drive amplifier, and the fourth amplifier 122 may be a power amplifier. Further, the second signal, which is amplified and output from the second front-end module 120, may have a lower frequency than the first signal amplified and output from the first front-end module 110. The second signal may be, for instance, but not limited to, a signal having a frequency band of 2 GHz.

The first amplifier 111 of the first front-end module 110 may receive first power from a first power terminal VCC1, and the second amplifier 112 may receive second power from a second power terminal VCC2. The third amplifier 121 of the second front-end module 120 may receive third power from a third power terminal VCC3, and the fourth amplifier 122 may receive fourth power from a fourth power terminal VCC4. Here, the first to fourth power may be different voltages or the same voltage. Therefore, the same power may be transmitted to the first to fourth amplifiers 111, 112, 121 and 122 through the first to fourth power terminals VCC1 to VCC4. Further, the first front-end module 110 and the second front-end module 120 may further comprise one or more capacitors for fine tuning to secure a return loss value according to the frequency band of the input signal and one or more capacitors for removing noise generated in the process of amplifying the signal. For instance, a first capacitor C1 may be included in the first front-end module 110 to be used for fine tuning, and a second capacitor C2 may be comprised in the first front-end module 110 to be used for noise removal. And, a third capacitor C3 may be included in the second front-end module 120 to be used for fine tuning. The second front-end module 120 may share the first capacitor C1 and the second capacitor C2 with the first front-end module 110 to use the first capacitor C1 and the second capacitor C2 for fine tuning and noise removal. That is, the first front-end module 110 and the second front-end module 120 can share capacitors. Here, the first capacitor C1 and the third capacitor C3 may be capacitors having a very small capacity of pF (picofarad), and the second capacitor C2 may be a capacitor having a capacity of μF (microfarad). As an example, the first capacitor C1 may have a capacity of 12 pF, the second capacitor C2 may have a capacity of 1 μF, and the third capacitor C3 may have a capacity of 27 pF. In an example of connection relationship between capacitors shared by the first front-end module 110 and the second front-end module 120, the first capacitor C1 may be connected to the first power terminal VCC1 which transmits the first power to the first amplifier 111, and the second capacitor C2 may be connected to the second power terminal VCC2 which transmits the second power to the second amplifier 112. At this time, the first power terminal VCC1 may be shared since the second capacitor C2 is connected to the second power terminal VCC2. The third capacitor C3 may be connected to the third power terminal VCC3 which transmits the third power to the third amplifier 121, and the first capacitor C1 and the second capacitor C2 may be connected to the fourth power terminal VCC4 which transmits the fourth power to the fourth amplifier 122.

The first capacitor C1 and the second capacitor C2 may be arranged between the first front-end module 110 and the second front-end module 120. Thus, the length of a power line for supplying power to the first front-end module 110 and the second front-end module 120 can be shortened. Further, the first front-end module 110 and the second front-end module 120 can easily share the capacitors as described above.

In the embodiment of the present disclosure, the first front-end module 110 may further include a fifth amplifier 113. The fifth amplifier 113 may be connected between the first input terminal RFin1 and the first amplifier 111 and may amplify the first signal input to the first input terminal RFin1 to transmit the amplified first signal to the first amplifier 111. That is, the first front-end module 110 may transmit the first signal, which is input to the first input terminal RFin1, to the second amplifier 112 after amplifying the first signal twice by the fifth amplifier 113 and the first amplifier 111. However, since the second front-end module 120 processes a signal having a lower frequency than the signal processed by the first front-end module 110, an output voltage of the second signal of the second front-end module 120 may be higher than an output voltage of the first signal of the first front-end module 110. Therefore, the second front-end module 120 can transmit the second signal to the fourth amplifier 122 after amplifying the second signal once by the third amplifier 121. However, without being limited thereto, the second front-end module 120 may further include one or more amplifiers (not shown), which amplify the second signal before transmitting the second signal to the third amplifier 121, to transmit the second signal to the third amplifier 121 after amplifying the second signal input to the second input terminal RFin2 when processing a high output signal.

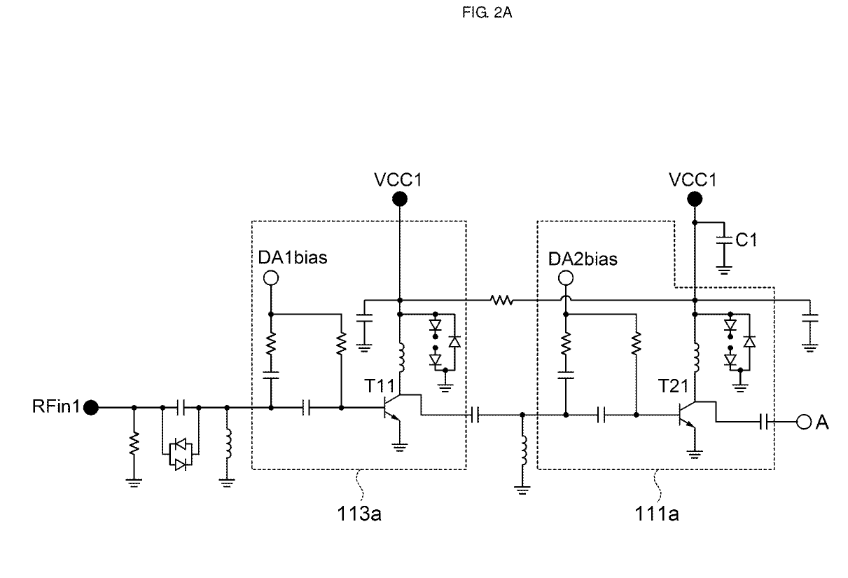

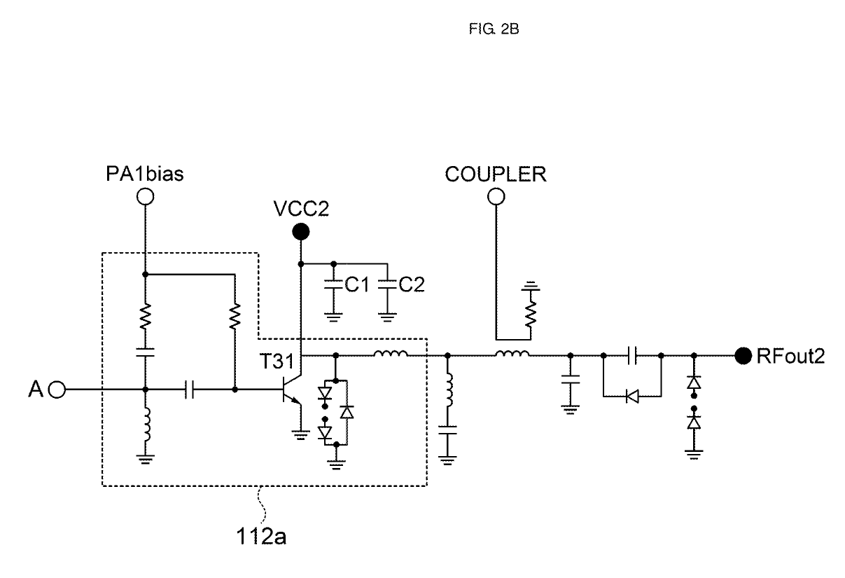

FIG. 2A is a partial circuit diagram showing a portion of the first front-end module shown in FIG. 1, and FIG. 2B is a partial circuit diagram showing another portion of the first front-end module shown in FIG. 1.

Referring to FIGS. 2A and 2B, the first front-end module 110 may receive and amplify a signal having a high frequency to output the amplified signal. Thus, the first front-end module 110 may include a first drive amplifier 113a, a second drive amplifier 111a, and a first power amplifier 112a. Here, the second drive amplifier 111a and the first power amplifier 112a may correspond to the first amplifier 111 and the second amplifier 112 of FIG. 1, respectively, and the first drive amplifier 113a may correspond to the fifth amplifier 113 of FIG. 1.

The first drive amplifier 113a may include a first transistor T11, and the first signal having a high frequency may be transmitted to a base of the first transistor T11. At this time, a bias voltage may be transmitted to the base of the first transistor T11 so that the first transistor T11 can perform normal operation. And, the first power may be transmitted to an emitter of the first transistor T11 from the first power terminal VCC1 to amplify and output the first signal. The second drive amplifier 111a may include a second transistor T21, and the first signal amplified by the first drive amplifier 113a may be transmitted to a base of the second transistor T21. At this time, a bias voltage may be transmitted to the base of the second transistor T21 so that the second transistor T2 can perform normal operation. And, the first power may be transmitted to an emitter of the second transistor T21 from the first power terminal VCC1 to amplify the first signal again and output the further amplified first signal. The first drive amplifier 113a and the second drive amplifier 111a may be connected to one or more capacitors for fine tuning, respectively. Therefore, the first capacitor C1 may be connected to the first power terminal VCC1 of the first drive amplifier 113a and the second drive amplifier 111a. The first power amplifier 112a may include a third transistor T31, and the input signal amplified by the second drive amplifier 111a may be transmitted to a base of the third transistor T31. At this time, a bias voltage may be transmitted to the base of the third transistor T31 so that the third transistor T31 can perform normal operation. And, the second power may be transmitted to an emitter of the third transistor T31 from the second power terminal VCC2 to amplify the first signal again and output the further amplified first signal. At this time, a capacitor for noise removal may be connected to the first power amplifier 112a. For instance, the second capacitor C2 can be connected to the second power terminal VCC2. Further, since the first power amplifier 112a may share the first capacitor C1 with the first drive amplifier 113a and/or the second drive amplifier 111a, the first capacitor C1 connected to the first power terminal VCC1 of the first drive amplifier 113a and the second drive amplifier 111a can be connected to the first power terminal VCC1.

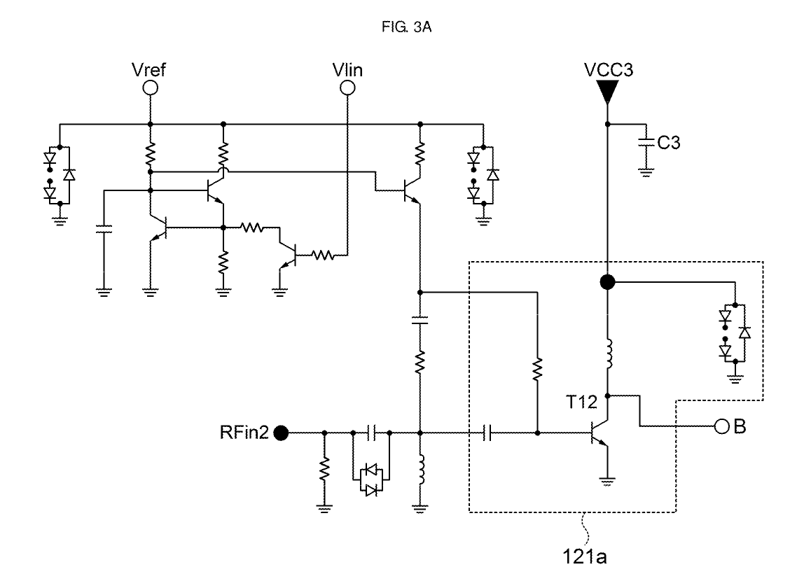

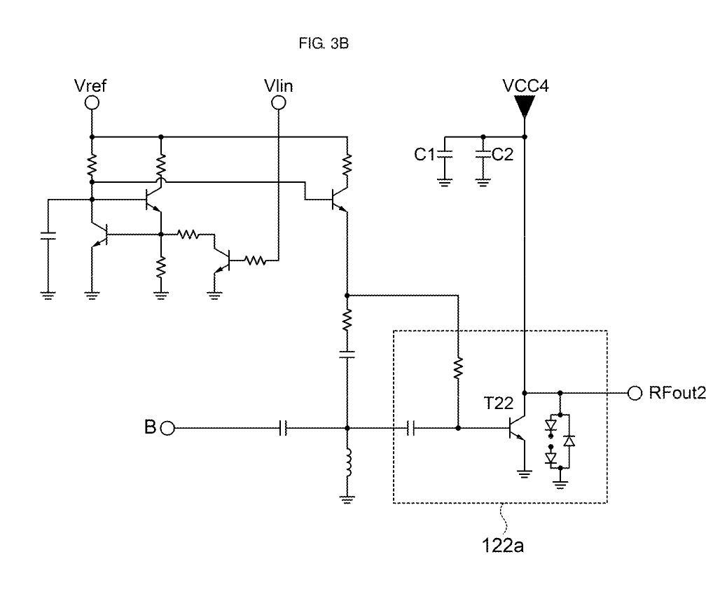

FIG. 3A is a partial circuit diagram showing a portion of the second front-end module shown in FIG. 1, and FIG. 3B is a partial circuit diagram showing another portion of the second front-end module shown in FIG. 1.

Referring to FIGS. 3A and 3B, the second front-end module 120 may receive and amplify the second signal having a frequency lower than that of the signal processed by the first front-end module 110 to output the amplified second signal. Thus, the second front-end module 120 may include a third drive amplifier 121a and a second power amplifier 122a. Here, the third drive amplifier 121a and the second power amplifier 122a may correspond to the third amplifier 121 and the fourth amplifier 122 of FIG. 1, respectively.

The third drive amplifier 121a may include a fourth transistor T12, and a base of the fourth transistor T12 may be connected to the second input terminal RFin2 to receive the second signal. At this time, a bias voltage may be transmitted to the base of the fourth transistor T12 so that the fourth transistor T12 can perform normal operation. And, the third power may be transmitted to an emitter of the fourth transistor T12 from the third power terminal VCC3 to amplify and output the second signal. A capacitor for fine tuning may be connected to the third drive amplifier 121a. For example, the third capacitor C3 can be connected to the third power terminal VCC3 of the third drive amplifier 121a. The second power amplifier 122a may include a fifth transistor T22, and the second signal amplified by the third drive amplifier 121a may be transmitted to a base of the fifth transistor T22. At this time, a bias voltage may be transmitted to the base of the fifth transistor T22 so that the fifth transistor T22 can perform normal operation. And, the fourth power may be transmitted to an emitter of the fifth transistor T22 from the fourth power terminal VCC4 to amplify the input signal again and output the further amplified signal. A capacitor for noise removal may be connected to the second power amplifier 122a. For instance, the second capacitor C2 can be connected to the fourth power terminal VCC4. Further, since the second power amplifier 122a shares the first capacitor C1 with the third drive amplifier 121a, the first capacitor C1 connected to the third power terminal VCC3 of the third drive amplifier 121a can be connected to the first power terminal VCC1.

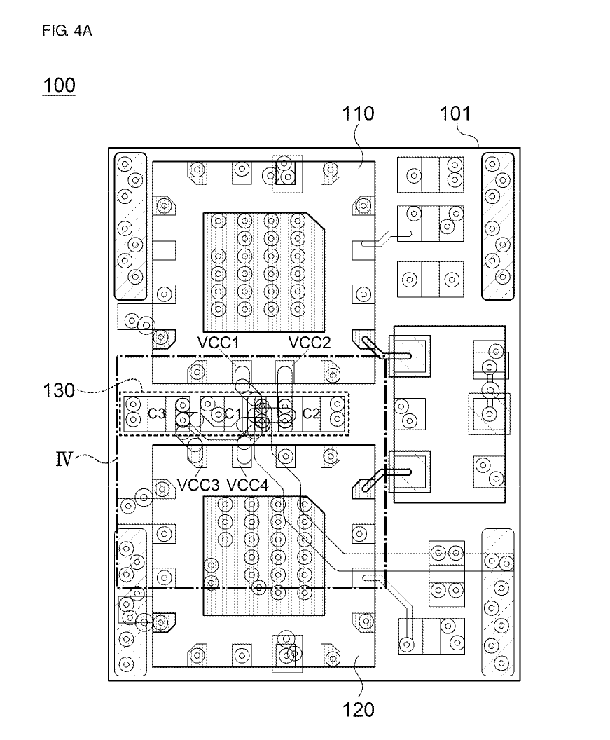

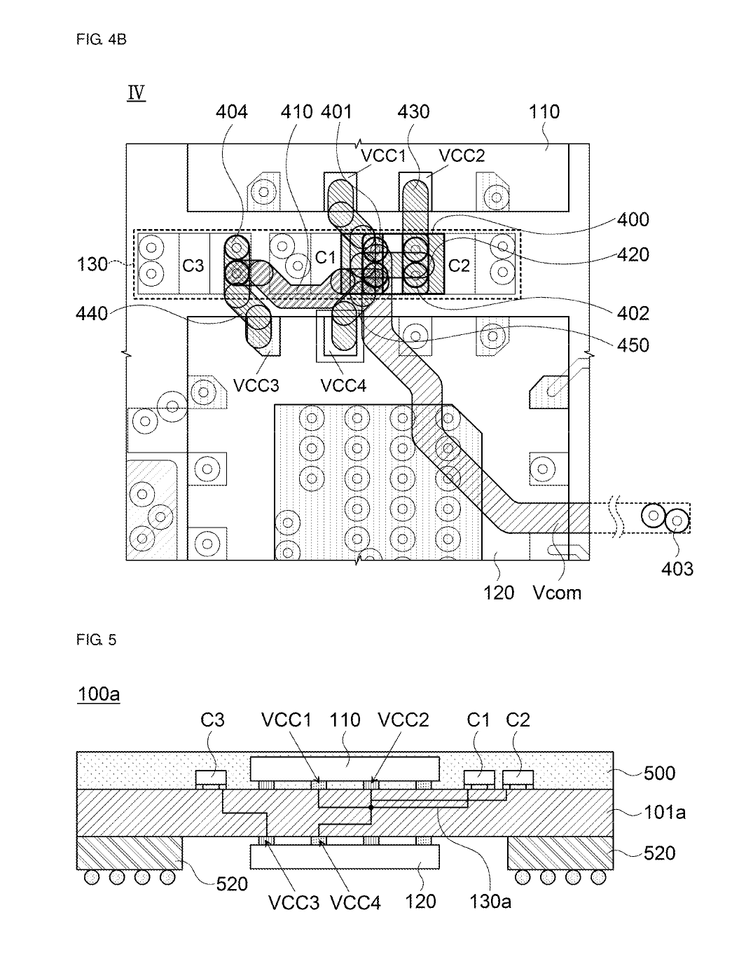

FIG. 4A is a layout diagram showing an embodiment in which the wireless communication module shown in FIG. 1 is mounted on a substrate, and FIG. 4B is a layout diagram enlarging a portion IV in which the first capacitor C1, the second capacitor C2, and the third capacitor C3 shown in FIG. 4A are connected.

Referring to FIGS. 4A and 4B, the wireless communication module 100 may include the first front-end module 110, the second front-end module 120, and the wiring unit 130 arranged between the first front-end module 110 and the second front-end module 120 to supply power to the first front-end module 110 and the second front-end module 120.

The first front-end module 110 may be formed on the top of a substrate 101, and the second front-end module 120 may be formed on the bottom of the substrate 101. Since the wiring unit 130 is arranged between the first front-end module 110 and the second front-end module 120, the length of wirings, which supply power to the first front-end module 110 and the second front-end module 120, in the wiring unit 130 can be minimized, thus increasing current transmission efficiency.

The wiring unit 130 may include a common power, an electrode plate 400, a first wiring 410, and a second wiring 420. The common power line Vcom may be arranged on the substrate 101. The electrode plate 400 may be arranged on the common power line Vcom to be connected to the common power line Vcom through a first via 401. The first wiring 410 may be arranged on the common power line Vcom to be connected to the electrode plate 400. The second wiring 420 may be arranged on the electrode plate 400 to be connected to the electrode plate 400 through a second via 402.

The common power line Vcom may be connected to the outside of the wireless communication module 100 to supply the power required for the operation of the first front-end module 110 and the second front-end module 120 arranged on the substrate 101. The first front-end module 110 may include the first power terminal VCC1 and the second power terminal VCC2. The first power terminal VCC1 and the second power terminal VCC2 may be connected to the substrate 101 to receive power. The second front-end module 120 may include the third power terminal VCC3 and the fourth power terminal VCC4. The third power terminal VCC3 and the fourth power terminal VCC4 may be connected to the substrate 101 to receive power. And, the electrode plate 400 arranged on the common power line Vcom may be electrically connected to the common power line Vcom through the first via 401. For example, the electrode plate 400 may be formed not in the shape of a line but in the shape of a plate, and therefore, the area of the electrode plate 400 to which a current is transmitted may be wider than the case in which the electrode plate 400 is formed in the shape of a line. Since the electrode plate 400 may be formed in the shape of a plate, the first via 401 may include at least two vias. When the first via 401 includes the at least two vias, a current transmission path may be increased to smoothly transmit a current to the electrode plate 400. A third via 403 may be formed in a power input terminal of the common power line Vcom, which receives external power, to connect the common power line Vcom to the external power. The third via 403 may include at least two vias, thus smoothly transmitting a current to the common power line Vcom. Further, the first wiring 410 may be formed together when the electrode plate 400 is formed, and the first wiring 410 may be connected to the electrode plate 400. And, a third wiring 430 connected to the first power terminal VCC1 of the first front-end module 110, a fourth wiring 440 connected to the second power terminal VCC2 of the first front-end module 110, a fifth wiring 450 connected to the third power terminal VCC3 of the second front-end module 120, and a sixth wiring 460 connected to the fourth power terminal VCC4 of the second front-end module 120 may be connected to the second wiring 420 arranged on the electrode plate 400 and the first wiring 410. Further, the second wiring 420 may be connected to the electrode plate 400 through the second via 402 to smoothly receive a current from the electrode plate 400. The second via 402 may include at least two vias, and the fifth wiring 450 may be connected to the first wiring 410 through a fourth via 404 to receive a current from the electrode plate 400.

Since the electrode plate 400 can be formed in the shape of a plate, the wiring between the common power line Vcom and the first power terminal VCC1 and the second power terminal VCC2 of the first front-end module 110 and between the common power line Vcom and the third power terminal VCC3 and the fourth power terminal VCC4 of the second front-end module 120 can be shortened by the electrode plate 400, thus reducing the transmission loss of a current flowing from the common power line Vcom to the first front-end module 110 and/or the second front-end module 120.

In the wireless communication module 100, the first capacitor C1 may be further connected to the third wiring 430 and the fifth wiring 450, the second capacitor C2 may be further connected to the second wiring 420, and the third capacitor C3 may be further connected to the fifth wiring 450. Thus, the first front-end module 110 and the second front-end module 120 can share the capacitors.

FIG. 5 is a structural diagram showing the wireless communication module, shown in FIG. 1, formed in a multilayer structure.

Referring to FIG. 5, in a wireless communication module 100a, the first front-end module 110 may be arranged on the top of a substrate 101a, and the second front-end module 120 may be arranged on the bottom of the substrate 101a. Since the first front-end module 110 and the second front-end module 129 are arranged on the top and bottom of the substrate 101a, the wireless communication module 100a can have a multilayer structure. And, the first capacitor C1, the second capacitor C2, and the third capacitor C3 may be arranged on the top of the substrate 101a. A wiring 130a may be formed in the substrate 101a. By the wiring 130a formed in the substrate 101a, the first power terminal VCC1 and the second power terminal VCC2 of the first front-end module 110 and the first capacitor C1 may be electrically connected to each other. The second power terminal VCC2 of the first front-end module 110 and the second capacitor C2 may be electrically connected to each other. Further, the third power terminal VCC3 of the second front-end module 120 and the second capacitor C2 may be electrically connected to each other. And, the third power terminal VCC3 of the second front-end module 120 and the third capacitor C3 may be electrically connected to each other. Thus, the first front-end module 110 and the second front-end module 120 can share the capacitors.

A mold 500 may be formed on the top surface of the substrate 101a on which the first front-end module 110 is arranged. A sub substrate 520 may be arranged on the bottom surface of the substrate 101a on which the second front-end module 120 is arranged.

According to some embodiments of the wireless communication module of the present disclosure, it is possible to reduce manufacturing costs by reducing the number of components. Further, it is possible to improve current transmission efficiency by implementing a short current transmission line.

In the claims hereof, any element expressed as a means for performing a specified function is intended to encompass any way of performing that function including, for example, a combination of circuit elements which performs that function or software in any form, including, therefore, firmware, microcode or the like, combined with appropriate circuitry for executing that software to perform the function.

Reference in the specification to “an embodiment” of the present principles, as well as other variations thereof, means that a particular feature, structure, characteristic, and so forth described in connection with the embodiment is included in at least one embodiment of the present principles. Thus, the appearances of the phrase “in an embodiment”, as well as any other variations, appearing in various places throughout the specification are not necessarily all referring to the same embodiment.

Reference in the specification to “connect” or “connecting”, as well as other variations thereof, means that an element is directly connected to the other element or indirectly connected to the other element through another element. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

What is claimed is:

1. A wireless communication module comprising:
a first front-end module;
a second front-end module; and
a wiring unit arranged between the first front-end module and the second front-end module to supply power to the first front-end module and the second front-end module, wherein at least one capacitor is connected to the wiring unit.

2. The wireless communication module according to claim 1, wherein the wiring unit comprises:
an electrode plate arranged on a common power line, which receives the power from an outside of the wireless communication module, and connected to the common power line through a first via;
a first wiring arranged on the common power line and connected to the electrode plate; and
a second wiring arranged on the electrode plate and connected to the electrode plate through a second via.

3. The wireless communication module according to claim 2, wherein the first front-end module is configured to receive the power through a first power terminal and a second power terminal and comprises:
a third wiring connected to the second wiring and the first power terminal to supply the power; and
a fourth wiring connected to the second wiring and the second power terminal to supply the power.

4. The wireless communication module according to claim 3, wherein the second front-end module is configured to receive the power through a third power terminal and a fourth power terminal and comprises:
a fifth wiring connected to the first wiring through a third via and connected to the first wiring and the third power terminal; and
a sixth wiring connected to the second wiring and the fourth power terminal.

5. The wireless communication module according to claim 3, wherein the first via comprises at least two vias.

6. The wireless communication module according to claim 3, wherein the second via comprises at least two vias.

7. The wireless communication module according to claim 2, wherein the first front-end module is arranged on a top of a substrate, and the second front-end module is arranged on a bottom of the substrate.

8. The wireless communication module according to claim 7, wherein the first front-end module and the second front-end module are arranged on both surfaces of the substrate, respectively, and the wiring unit is formed in the substrate.

9. A wireless communication module comprising:
a first front-end module;
a second front-end module;
a first capacitor arranged between the first front-end module and the second front-end module, and connected to a power terminal of the first front-end module and a power terminal of the second front-end module; and
a second capacitor arranged between the first front-end module and the second front-end module, and connected to the power terminal of the first front-end module and the power terminal of the second front-end module.

10. The wireless communication module according to claim 9, further comprising:
a third capacitor arranged between the first front-end module and the second front-end module, and connected to the power terminal of the second front-end module.

11. The wireless communication module according to claim 9, wherein the first front-end module comprises a first amplifier and a second amplifier which are arranged between a first input terminal and a first output terminal in a cascade form,
the second front-end module comprises a third amplifier and a fourth amplifier which are arranged between a second input terminal and a second output terminal in a cascade form,
the first capacitor is connected to the first amplifier through a first power terminal and connected to the fourth amplifier through a second power terminal, and
the second capacitor is connected to the second amplifier through the second power terminal and is connected to the fourth amplifier through a fourth power terminal.

12. The wireless communication module according to claim 11, further comprising:
a third capacitor connected to the third amplifier through a third power terminal.

13. The wireless communication module according to claim 9, wherein the first front-end module and the second front-end module are arranged on a substrate.

14. The wireless communication module according to claim 9, wherein the first front-end module and the second front-end module are arranged on both surfaces of a substrate, respectively.

15. The wireless communication module according to claim 11, further comprising:
a fifth amplifier between the first input terminal and the first amplifier.
